(19) United States
(12) Patent Application Publication
(10) Pub. No.: US 2012/0241746 A1
(43) Pub. Date: Sep. 27, 2012

(54) ELECTROPHORESIS DISPLAY AND MANUFACTURING METHOD

(75) Inventors: Chunyan XIE, Beijing (CN); Zhuo ZHANG, Beijing (CN); Gang WANG, Beijing (CN); Cuili GAI, Beijing (CN)

(73) Assignee: BOE TECHNOLOGY GROUP CO., LTD., Beijing (CN)

(21) Appl. No.: 13/426,866

(22) Filed: Mar. 22, 2012

(30) Foreign Application Priority Data
Mar. 23, 2011 (CN) 201110070967.3

(51) Int. Cl. H01L 33/08

(52) U.S. Cl. 257/59; 438/34; 257/E33.053

(57) ABSTRACT

The disclosed technology is in connection with an electrophoresis display and manufacturing method thereof. The electrophoresis display comprises: a substrate; a gate line metal layer including a gate electrode, formed on the substrate; a gate insulating layer covering the gate line metal layer; a semiconductor active layer formed on the gate insulating layer and located above the gate electrode correspondingly; a data line metal layer including a source electrode and a drain electrode, formed on the gate insulating layer, wherein the source electrode and the drain electrode are located on the semiconductor active layer and separated by a distance; a photoresist resin layer covering the data line metal layer and formed with a via hole above the drain electrode; and a pixel electrode layer formed on the photoresist resin layer and connected to the drain electrode by the via hole.

### BACKGROUND

Embodiments of the disclosed technology relate to an electrophoresis display (EPD) and an EPD manufacturing method.

Electrophoresis display is a new display technology with characteristics of paper and electronic devices, and it can not only conform to people's visual habit but also can display conveniently and speedily. As one of key technologies of the electrophoresis display, so-called electronic ink technology disperses and suspends charged electrophoresis particles within a dispersant solution to form a suspension system. The electrophoresis particles can move in different directions by affection of an applied electrical field and display patterns and characters continuously based on need.

An electronic ink (E-ink) type electrophoresis display is a reflective type display, and may comprise a front covering board having a transparent electrode, an E-ink layer and a thin film transistor (TFT) array substrate. A semiconductor active layer adopted in the TFT array substrate is an amorphous silicon material layer. Typically, the amorphous silicon material is a photoconductivity material with a main defect of tending to degradation when exposed to light. When a large number of electrons and holes are produced, the dark-conduction and photoconductivity of the amorphous silicon material are degraded so that the leakage current of the thin film transistor is increased. Therefore, charges in the storage capacitor are leaked out, and thus displaying quality becomes poor.

### SUMMARY

According to one embodiment of the disclosed technology, an electrophoresis display is provided. The electrophoresis display comprises: a substrate; a gate line metal layer including a gate electrode, formed on the substrate; a gate insulating layer covering the gate line metal layer; a semiconductor active layer formed on the gate insulating layer and located above the gate electrode correspondingly; a data line metal layer including a source electrode and a drain electrode, formed on the gate insulating layer, wherein the source electrode and the drain electrode are located on the semiconductor active layer and separated by a distance; a photoresist resin layer covering the data line metal layer and formed with a via hole above the drain electrode; and a pixel electrode layer formed on the photoresist resin layer and connected to the drain electrode by the via hole.

According to another embodiment, a method for manufacturing an electrophoresis display is provided. The method comprises steps of: forming a gate line metal layer including a gate electrode on a substrate; forming a gate insulating layer and a semiconductor active layer on the gate line metal layer, the semiconductor active layer being located above the gate electrode; forming a data line metal layer including a source electrode and a drain electrode on the gate insulating layer, the source electrode and the drain electrode being located above the semiconductor active layer and being separated by a distance; applying a photoresist resin layer to the data line metal layer and forming a via hole connected with the drain electrode in the photoresist resin layer by a patterning process; forming a pixel electrode layer on the photoresist resin layer, the pixel electrode layer being connected to the drain electrodes by the via hole.

Further scope of applicability of the disclosed technology will become apparent from the detailed description given hereinafter. However, it should be understood that the detailed description and specific examples, while indicating embodiments of the disclosed technology, are given by way of illustration only, since various changes and modifications within the spirit and scope of the disclosed technology will become apparent to those skilled in the art from the following detailed description.

### BRIEF DESCRIPTION OF THE DRAWINGS

For purpose of more clearly describing embodiments of the disclosed technology or the prior art, accompanying figures used in the description of the embodiments or the prior art will be explained briefly below. Apparently, the figures in the description are only some embodiments of the disclosed technology. It is possible for those skilled in the art to obtain the other figures according to these figures without any creative work being made.

FIG. 1 is a first structure schematic diagram for showing a process of manufacturing an electrophoresis display according to a first embodiment of the disclosed technology;

FIG. 2 is a second structure schematic diagram for showing the process of manufacturing the electrophoresis display according to the first embodiment of the disclosed technology;

FIG. 3 is a third structure schematic diagram for showing the process of manufacturing the electrophoresis display according to the first embodiment of the disclosed technology;

FIG. 4 is a fourth structure schematic diagram for showing the process of manufacturing the electrophoresis display according to the first embodiment of the disclosed technology;

FIG. 5 is a fifth structure schematic diagram for showing the process of manufacturing the electrophoresis display according to the first embodiment of the disclosed technology;

FIG. 6 is a first structure schematic diagram for showing a process of manufacturing an electrophoresis display according to a second embodiment of the disclosed technology;

FIG. 7 is a second structure schematic diagram for showing the process of manufacturing the electrophoresis display according to the second embodiment of the disclosed technology; and

FIG. 8 is a third structure schematic diagram for showing the process of manufacturing the electrophoresis display according to the second embodiment of the disclosed technology.

### DETAILED DESCRIPTION

Hereinafter, the embodiments of the disclosed technology will be described in detail with reference to the accompanying figures so that the objects, technical solutions and advantages of the embodiments of the disclosed technology will become more apparent. It should be noted that the embodiments described below merely are a portion of but not all of the embodiments of the disclosed technology, and thus various modifications, combinations and alterations may be made on basis of the described embodiments without departing from the spirit and scope of the disclosed technology.

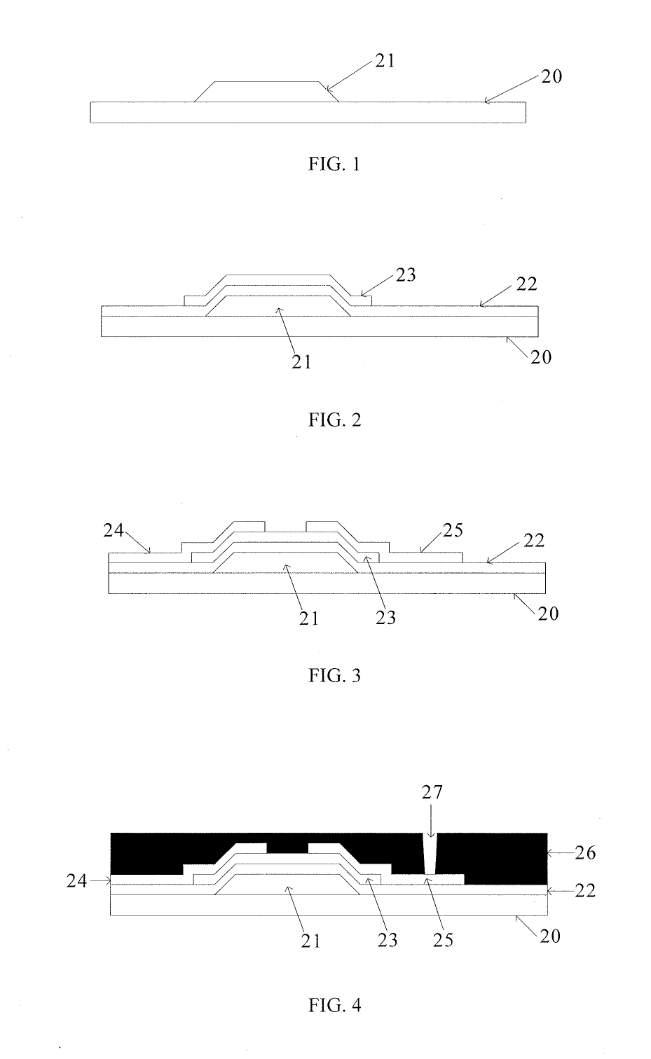

With reference to FIGS. 1 to 5, a method for manufacturing an electrophoresis display according to a first embodiment of the disclosed technology is described. The method comprises the following steps S101-S105.

S101: forming a gate line metal layer including a gate electrode on a substrate.

As shown in FIG. 1, a metal thin film having a thickness of 1000 Å to 7000 Å is formed on a substrate 20 by using a magnetron sputtering method. As the metal thin film, the thin film of a metal material such as Molybdenum, Aluminum, Aluminum and Nickel alloy, Molybdenum and Tungsten alloy, Chromium, Copper or the like, or any composite structure of the films of above-mentioned metal materials can be used. Then, a plurality of lateral gate lines (not shown) and gate electrodes 21 each connected to one of the gate lines are formed in a predetermined region on the substrate 20 by a patterning process. An example of a patterning process includes exposing by using a mask, development, etching, photoresist removing and the like. The substrate is formed by plastic or glass, for example.

S102: forming a gate insulating layer and a semiconductor active layer on the gate line metal layer, the semiconductor active layer being located above the gate electrode.

As shown in FIG. 2, a gate insulating layer 22 having a thickness of 1000 Å to 6000 Å, an amorphous silicon film having a thickness of 1000 Å to 6000 Å and an n+ (n doped) amorphous silicon film having a thickness of 500 Å to 1000 Å are deposited sequentially on the substrate 20 by using a chemical vapor depositing (CVD) method. The material of the gate insulating layer 22 may be silicon nitride, silicon oxide, silicon oxynitride or the like. Next, a photoresist layer is applied onto the amorphous silicon film and then is exposed and developed by using a mask for forming the active layer, and then the amorphous silicon film and the n+ amorphous silicon film are dry-etched by using the formed photoresist pattern as an etching mask, so as to form a semiconductor active layer 23 above the gate electrode 21.

S103: forming a data line metal layer including a source electrode and a drain electrode on the gate insulating layer, the source electrode and the drain electrode being located above the semiconductor active layer and being separated by a distance.

As shown in FIG. 3, a metal thin film having a thickness of 1000 Å to 7000 Å, similar to the gate line metal layer, is deposited on the substrate 20 by using a method similar to that for forming the gate lines. Then, the data lines (not shown), the source electrode 24 and the drain electrode 25 are formed in a predetermined region by a patterning process. A channel can be formed between the source electrode 24 and the drain electrode 25 which forms a thin film transistor together with the gate electrode 21.

Since the amorphous silicon film and the n+ amorphous silicon film are formed on the gate insulating film 22, it is necessary to etch away the n+ amorphous silicon film above the channel so as to form the channel in the step S103.

S104: applying a photoresist resin layer onto the data line metal layer and forming a via hole connected with the drain electrode in the photoresist resin layer by a patterning process.

As shown in FIG. 4, a photoresist resin is applied by first dropping centrally and then spin-coating to obtain a photoresist resin layer 26. Then, a via hole 27 is formed above the drain electrode 25 by using a patterning process.

In addition, as shown in FIG. 4, the upper surface of the photoresist resin layer 26 above the data line metal layer is planar. In this way, it is possible to increase the distance between the pixel electrode layer formed later and the source and drain electrodes, so as to enlarge the area of the pixel electrode layer and improve the aperture ratio.

Furthermore, the photoresist resin layer 26 can be an opaque photoresist resin layer, for example, which is made of the material for black matrix and/or of color resin used during manufacturing a color filter substrate. As a result, applying of the photoresist resin layer can be performed by using the apparatus for manufacturing the color filter substrate currently without adding any additional other apparatus, material or the like, thus the manufacturing cost can be decreased.

S105: forming a pixel electrode layer on the photoresist resin layer, the pixel electrode layer being connected to the drain electrode by a via hole.

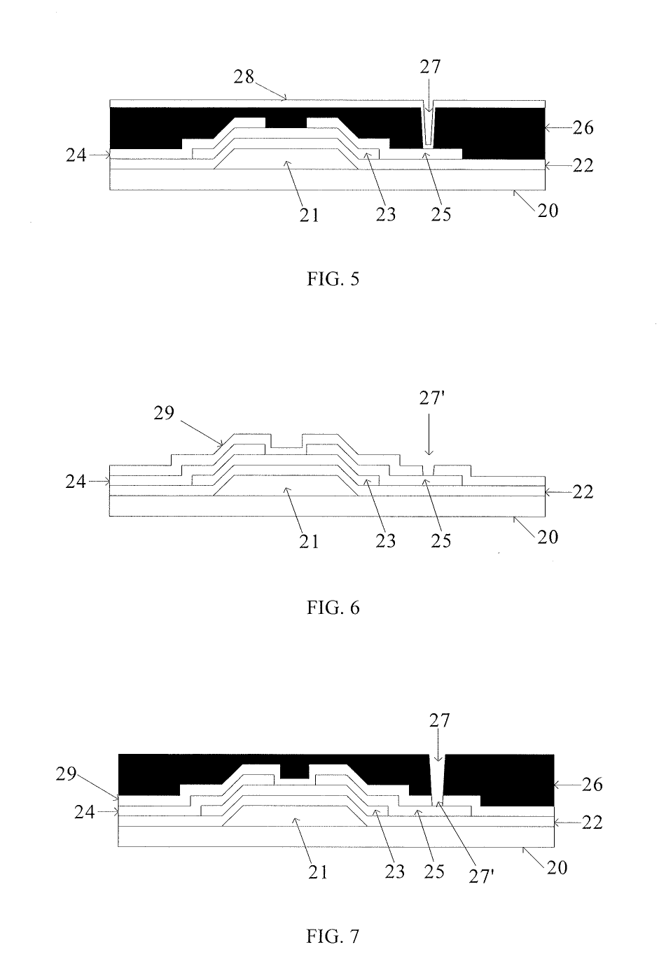

As shown in FIG. 5, a pixel electrode layer 28 is deposited on the photoresist resin layer 26 on the substrate by using a method similar to that for manufacturing the source electrodes and the drain electrodes. The pixel electrode layer 28 may be made of Indium Tin oxide (ITO) or Indium Zinc oxide (IZO) with a thickness of 100 Å to 1000 Å. The pixel electrode layer 28 is connected to the drain electrode 25 by a via hole 27.

In the method for manufacturing the electrophoresis display according to the disclosed technology, after forming a data line metal layer, a photoresist resin layer is applied. The photoresist resin layer can be used to protect the TFT without a process for forming a passivation layer; on the other hand, since the photoresist resin layer is opaque, it can prevent the amorphous silicon of the TFT semiconductor active layer from being irradiated by light, so as to reduce leakage current generated by the amorphous silicon and enhance the display effect.

A method for manufacturing an electrophoresis display according to a second embodiment of the disclosed technology comprises the following steps S201-S206.

S201: forming a gate line metal layer including a gate electrode on a substrate. S202: forming a gate insulating layer and a semiconductor active layer on the gate line metal layer, the semiconductor active layer being located above the gate electrode.

S203: forming a data line metal layer including a source electrode and a drain electrode on the gate insulating layer, the source electrode and the drain electrode being located above the semiconductor active layer and being separated by a distance.

The steps of S201 to S203 are identical with the steps of S101 to S103 in the first embodiment.

S204: forming a passivation layer on the data line metal layer and forming a via hole in the passivation layer connected with the drain electrode by a patterning process.

As shown in FIG. 6, a passivation layer 29 having a thickness of 1000 Å to 6000 Å is formed on the data line metal layer by using a method similar to that for forming the gate insulating layer and the semiconductor active layer, and the material of the passivation layer 29 may be silicon nitride, transparent organic resin material or the like. In this step, the gate lines and the data lines are covered by the passivation layer 29. Next, a connection via hole 27′ is formed above the drain electrode 25 by a mask using a patterning process.

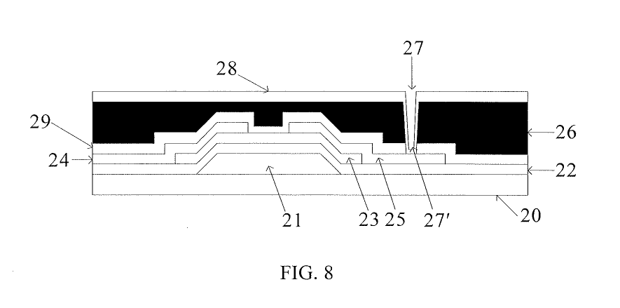

S205: as shown in FIG. 7, applying a photoresist resin layer 26 on the passivation layer 29 and forming a via hole 27, which corresponds to the via hole 27′ in the passivation layer 29 and connected with the drain electrode 25, in the photoresist resin layer 26 by a patterning process.

In addition, as shown in FIG. 7, the upper surface of the photoresist resin layer 26 above the passivation layer 29 is planar or flat. In this way, it is possible to increase the distance between the pixel electrode layer formed later and the source and drain electrodes, so as to enlarge the area of the pixel electrode layer and improve the aperture ratio.

Furthermore, the photoresist resin layer 26 can be an opaque photoresist resin layer, for example, which is made of the material for black matrix and/or color resin used during manufacturing a color filter substrate. As a result, applying of the photoresist resin layer can be performed by using the apparatus for manufacturing the color filter substrate currently without adding any additional apparatus, material or the like, thus the manufacturing cost can be decreased.

Here, since the via hole 27 in the photoresist resin layer 26 corresponds to the via hole 27′ in the passivation layer 29, the same mask can be used during exposure when the same kind of photoresist (e.g. positive or negative) is used.

S206: forming a pixel electrode layer 28 on the photoresist resin layer 26, the pixel electrode layer 28 being connected to the drain electrode 25 by the via hole 27 as shown in FIG. 8.

In the method for manufacturing the electrophoresis display according to the disclosed technology, after forming a data line metal layer and a passivation layer, a photoresist resin layer is applied. Since the photoresist resin layer is opaque, it can prevent the amorphous silicon of the TFT semiconductor active layer from being irradiated by light, so as to reduce leakage current generated by the amorphous silicon and enhance the display effect.

In addition, in the conventional technology, after forming the passivation layer of silicon nitride, since silicon nitride is hydrophilic, it is necessary to perform an modification process onto the surface of the passivation layer so that the planar resin layer can adhere to the passivation layer firmly, which increases the number of manufacturing processes and the cost for manufacturing the related structure. In this embodiment, since the photoresist resin layer is applied by using the process for manufacturing the color filter substrate, the modification process to the surface of the passivation layer is not required, which reduces the number of the processes and decrease the cost.

As shown in FIG. 5, the electrophoresis display according to the first embodiment of the disclosed technology comprises: a substrate 20; a gate line metal layer including a gate electrode 21, formed on the substrate 20; a gate insulating layer 22 covering the gate line metal layer; a semiconductor active layer 23 formed on the gate insulating layer and located above the gate electrode 21 correspondingly; a data line metal layer including a source electrode 24 and a drain electrode 25, formed on the gate insulating layer 22, wherein the source electrode 24 and the drain electrode 25 are located above the semiconductor active layer 23 and separated by a distance; a photoresist resin layer 26 covering the data line metal layer and formed with a via hole 27 above the drain electrode 25; a pixel electrode layer 28 formed on the photoresist resin layer 26 and connected to the drain electrode 25 by the via holes 27.

In this embodiment, the upper surface of the photoresist resin layer 26 above the data line metal layer is planar. In this way, it is possible to increase the distance between the pixel electrode layer formed later and the source and drain electrodes, so as to enlarge the area of the pixel electrode layer and improve the aperture ratio.

Furthermore, the photoresist resin layer 26 can be an opaque photoresist resin layer, for example, which is made of the material for black matrix and/or color resin used during manufacturing a color filter substrate. As a result, applying of the photoresist resin layer can be performed by using the apparatus for manufacturing the color filter substrate currently without adding any additional apparatus, material or the like, thus the manufacturing cost can be decreased.

For the electrophoresis display according to the disclosed technology, after forming a data line metal layer, a photoresist resin layer is applied. The photoresist resin layer can be used to protect the TFT without a process for forming a passivation layer; on the other hand, since the photoresist resin layer is opaque, it can prevent the amorphous silicon of the TFT semiconductor active layer from being irradiated by light, so as to reduce leakage current generated by the amorphous silicon and enhance the display effect.

As shown in FIG. 8, the electrophoresis display according to the second embodiment of the disclosed technology can comprise: a substrate 20; a gate line metal layer including a gate electrode 21, formed on the substrate 20; a gate insulating layer 22 covering the gate line metal layer; a semiconductor active layer 23 formed on the gate insulating layer and located above the gate electrode 21 correspondingly; a data line metal layer including a source electrode 24 and a drain electrode 25, formed on the gate insulating layer 22, wherein the source electrode 24 and the drain electrode 25 are located above the semiconductor active layer 23 and separated by a distance; a passivation layer 29 formed on the data line metal layer and formed with a via hole 27′ above the drain electrode 25; a photoresist resin layer 26 covering the passivation layer 29 and formed with a via hole 27 corresponding to the via hole 27′ of the passivation layer 29 above the drain electrode 25; a pixel electrode layer 28 formed on the photoresist resin layer 26 and connected to the drain electrode 25 by the via hole 27.

In this embodiment, the upper surface of the photoresist resin layer 26 covering above the data line metal layer is planar. In this way, it is possible to increase the distance between the pixel electrode layer formed later and the source and drain electrodes, so as to enlarge the area of the pixel electrode layer and improve the aperture ratio.

Furthermore, the photoresist resin layer 26 can be an opaque photoresist resin layer, for example, which is made of the material for black matrix and/or color resin used during manufacturing a color filter substrate. As a result, applying of the photoresist resin layer can be performed by using the apparatus for manufacturing the color filter substrate currently without adding any additional apparatus, material or the like, thus the manufacturing cost can be decreased.

For the electrophoresis display according to the disclosed technology, after forming a data line metal layer, a photoresist resin layer is applied. The photoresist resin layer can be used to protect the TFT without a process for forming a passivation layer; on the other hand, since the photoresist resin layer is opaque, it can prevent the amorphous silicon of the TFT semiconductor active layer from being irradiated by light, so as to reduce leakage current generated by the amorphous silicon and enhance the display effect.

In addition, in the conventional technology, after forming the passivation layer of silicon nitride, since silicon nitride is hydrophilic, it is necessary to perform a modification process to the surface of the passivation layer so that the planar resin layer can adhere to the passivation layer firmly, which increases the number of manufacturing processes and the cost for manufacturing the related structure. In this embodiment, since the photoresist resin layer is applied by using the process for manufacturing the color filter substrate, the modification process to the surface of the passivation layer is not required, which reduces the number of the processes and decrease the cost.

It should be appreciated that the embodiments described above are intended to illustrate but not limit the disclosed technology. Although the disclosed technology has been described in detail herein with reference to the embodiments, it should be understood by those skilled in the art that the disclosed technology can be modified, alternated or substituted and some of the technical features can be equivalently substituted without departing from the spirit and scope of the disclosed technology.

What is claimed is:

1. An electrophoresis display comprising:
a substrate;
a gate line metal layer including a gate electrode, formed on the substrate;
a gate insulating layer covering the gate line metal layer;
a semiconductor active layer formed on the gate insulating layer and located above the gate electrode correspondingly;
a data line metal layer including a source electrode and a drain electrode, formed on the gate insulating layer, wherein the source electrode and the drain electrode are located on the semiconductor active layer and separated by a distance;
a photoresist resin layer covering the data line metal layer and formed with a via hole above the drain electrode; and
a pixel electrode layer formed on the photoresist resin layer and connected to the drain electrode by the via hole.

2. The electrophoresis display according to claim 1, further comprising a passivation layer being located between the data line metal layer and the photoresist resin layer, wherein the passivation layer covers the data line metal layer and is provided with a via hole corresponding to the via hole in the photoresist resin layer above the drain electrode.

3. The electrophoresis display according to claim 1, wherein an upper surface of the photoresist resin layer covering the data line metal layer is planar.

4. The electrophoresis display according to claim 2, wherein an upper surface of the photoresist resin layer covering the data line metal layer is planar.

5. The electrophoresis display according to claim 1, wherein the photoresist resin layer is an opaque photoresist resin layer.

6. The electrophoresis display according to claim 2, wherein the photoresist resin layer is an opaque photoresist resin layer.

7. The electrophoresis display according to claim 5, wherein the photoresist resin layer is a resin layer made of the material for black matrix and/or color resin.

8. The electrophoresis display according to claim 6, wherein the photoresist resin layer is a resin layer made of the material for black matrix and/or color resin.

9. A method for manufacturing an electrophoresis display comprising steps of:
forming a gate line metal layer including a gate electrode on a substrate;
forming a gate insulating layer and a semiconductor active layer on the gate line metal layer, the semiconductor active layer being located above the gate electrode;
forming a data line metal layer including a source electrode and a drain electrode on the gate insulating layer, the source electrode and the drain electrode being located above the semiconductor active layer and being separated by a distance;
applying a photoresist resin layer to the data line metal layer and forming a via hole connected with the drain electrode in the photoresist resin layer by a patterning process; and
forming a pixel electrode layer on the photoresist resin layer, the pixel electrode layer being connected to the drain electrodes by the via hole.

10. The method according to claim 9, wherein after forming the data line metal layer and before applying the photoresist resin layer, the method further comprising:
forming a passivation layer on the data line metal layer, forming a via hole connected with the drain electrode in the passivation layer by a patterning process, wherein the via hole corresponds to the via hole in the photoresist resin layer.

11. The method according to claim 9, wherein an upper surface of the applied photoresist resin layer is planar.

12. The method according to claim 10, wherein an upper surface of the applied photoresist resin layer is planar.

13. The method according to claim 9, wherein the applied photoresist resin layer is an opaque photoresist resin layer.

14. The method according to claim 10, wherein the applied photoresist resin layer is an opaque photoresist resin layer.

15. The method according to claim 9, wherein the applied photoresist resin layer is a resin layer made of the material for black matrix and/or color resin.

16. The method according to claim 10, wherein the applied photoresist resin layer is a resin layer made of the material for black matrix and/or color resin.
